(19) United States
(12) Patent Application Publication
(10) Pub. No.: US 2025/0224750 A1
(43) Pub. Date: Jul. 10, 2025

(54) VOLTAGE REGULATION SYSTEM

(71) Applicant: Micron Technology, Inc., Boise, ID (US)

(72) Inventors: Leon Zlotnik, Camino, CA (US); Ekram H. Bhuiyan, Sunnyvale, CA (US)

(21) Appl. No.: 18/980,712

(22) Filed: Dec. 13, 2024

Related U.S. Application Data
(60) Provisional application No. 63/617,709, filed on Jan. 4, 2024.

(51) Int. Cl. G05F 1/575; G05F 1/567; G05F 1/573

(52) U.S. Cl. CPC G05F 1/575; G05F 1/567; G05F 1/573

(57) ABSTRACT

Control circuitry is coupled to a first voltage regulation circuit and a second voltage regulation circuit. The control circuitry determines whether a signal criterion is met or not. In response to the determination that the signal criterion has been met, the control circuitry controls application of a current generated by first voltage regulation circuit and the second voltage regulation circuit to adjust a ratio between current levels corresponding to the signals generated by the first and second voltage regulation circuits.

### PRIORITY INFORMATION

This application claims the benefit of U.S. Provisional Application No. 63/617,709, filed on Jan. 4, 2023, the contents of which are incorporated herein by reference.

### TECHNICAL FIELD

Embodiments of the disclosure relate generally to a voltage regulation system and, in particular, to electronic systems that include a voltage regulation system.

### BACKGROUND

Various types of electronic devices such as logic circuits may store and process data. A logic circuit is an electronic circuit that processes digital signals or binary information, which can take on two possible values (usually represented as 0 and 1). The logic circuit can use logic gates to manipulate and transform the signals or binary information. Digital logic circuits can be used in a wide range of electronic devices including, for example, computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes a voltage regulation component in accordance with some embodiments of the present disclosure.

FIG. 2 illustrates an example of a voltage regulation system in accordance with some embodiments of the present disclosure.

FIG. 3 is a graph that illustrates controlling respective current levels of different voltage regulation circuits in accordance with some embodiments of the present disclosure.

FIG. 4 is a flow diagram corresponding to a method for a voltage regulation system in accordance with some embodiments of the present disclosure.

FIG. 5 is a block diagram of an example computer system in which embodiments of the present disclosure may operate.

### DETAILED DESCRIPTION

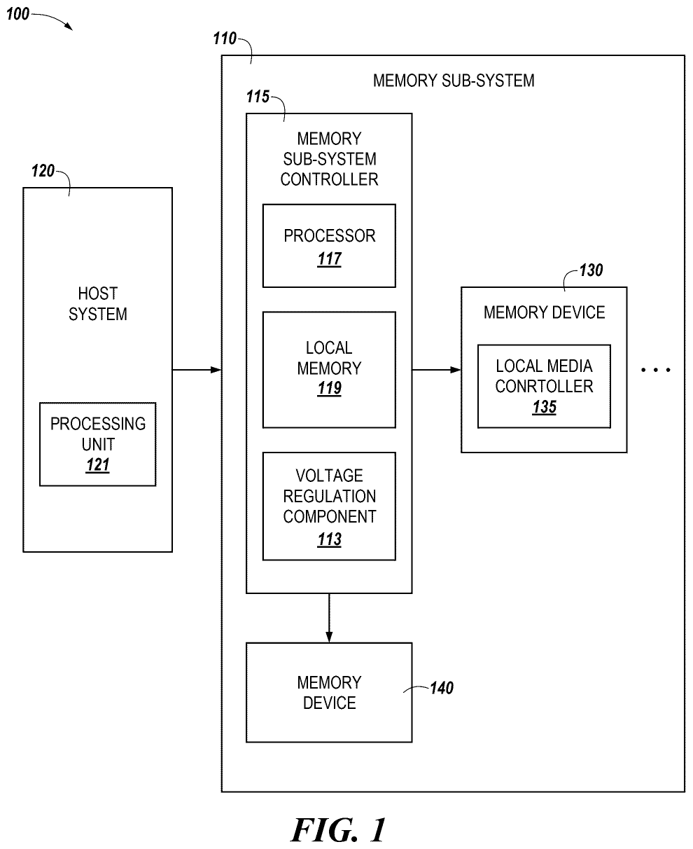

Aspects of the present disclosure are directed to a voltage regulation system and, in particular, to electronic systems that include a voltage regulation component. Example electronic systems, or portions thereof, in which embodiments of the present disclosure can operate include, but are not limited to a computing system, a system-on-chip (SoC), a networking system, a communication system, a memory system (e.g., a storage system, a memory module, etc.), an artificial intelligence (AI) system, and a digital entertainment system, among various other types of systems or combinations thereof. Examples electronic systems are described below in conjunction with FIG. 1.

Power in systems can be provided by various power supplies (referred to as “external power supplies”), which generally supply a voltage signal or current signal to one or more voltage regulators. Each voltage regulator then seeks to provide the supply voltage that is sufficient for operation of respective components of the electronic system; however, due to the need of high performance operation of the electronic system, one voltage regulator, which typically operates with insufficient current supply limit, may not be sufficient to supply the required output voltage or current to the components.

In some approaches, one or more additional voltage regulators that include a current supply with a higher margin (e.g., limit) can be utilized to compensate (e.g., boost) this lower current supply limit from the one voltage regulator. However, these additional voltage regulators may operate in a relatively power-inefficient manner, for instance, as the additional voltage regulators consume more input power to supply the same amount of output power (e.g., power supplied to devices) as the main voltage regulator. Further, a voltage regulation system may lack a mechanism that can dynamically optimize and/or control the usage of these additional voltage regulators. Therefore, such approaches may have to activate the additional voltage regulators sufficiently early enough to avoid an individual (e.g., the main voltage regulator) from being overloaded and/or to avoid supplying an insufficient amount of power to a system. As a result, such may result in substantially inefficient power consumption by operating the additional voltage regulators in a power-inefficient manner and/or may otherwise pose various challenges associated with attempting to optimize the voltage supplied to a system.

In order to address these and other deficiencies of current approaches, embodiments of the present disclosure provide for a sensing and voltage control mechanism that can dynamically control the usage of a secondary (“companion”) voltage regulator (in addition to a main voltage regulator) based on the need of the secondary voltage regulator, which eliminates and/or reduce the above-mentioned issues. In a number of embodiments, the secondary voltage regulator can start operating along with the main voltage regulator when the main voltage regulator meets its current limit.

In contrast to those approaches where the secondary voltage regulator, once activated to supply a current with a certain trend, is not further controlled (e.g., such that the trend remains constant), embodiments of the present disclosure provide a (e.g., dynamic) control of the secondary voltage regulator even subsequent to the activation. While activating and controlling of the secondary voltage regulator in a static manner further necessitates activation of the secondary voltage regulator at a relatively early point to avoid the other regulators (e.g., the main voltage regulator) being overloaded, embodiments of the present disclosure allows the secondary voltage regulator to be activated at a relatively later point (which reduces the inefficient power consumption from the secondary voltage regulator) and cause the secondary voltage regulator to be involved “more” as the risk of the main voltage regulator being overloaded increases.

FIG. 1 illustrates an example electronic system 100 that includes a host 102, a controller 104, and a device 106 in accordance with various embodiments of the present disclosure. While the electronic system 100 can be considered as an apparatus, embodiments are not so limited. For example, the host 102, the controller 104, and the device 106 can each separately be considered as an apparatus.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 104 via a physical and/or logical host interface that operates based on various communication protocols and to provide control, address, data, and other signals to the controller 104 (e.g., to further cause the controller 104 to control the device 106). Examples of the interface between the host 102 and the controller 104 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 104 is communicatively coupled to one or more electronic devices 106 such that signaling can be exchanged therebetween. Non-limiting examples of the devices 106 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 104 can include a processing device (e.g., processor 117) that can execute instructions stored in a local memory 119 to perform various operations described herein. The controller 104 can include various special purpose circuitry in the form of an ASIC, FPGA, state machine, and/or other logic circuitry that can perform operations described herein. As an example, the controller 104 can be a memory controller.

In various embodiments, one or more constituent components (e.g., host 102, controller 104, device 106, etc.) of system 100 can be part of a SoC. In one example, a device 106 itself can correspond to an SoC, while the host 102 and the controller 104 are considered “external” to the SoC. In another example, the host 102 or the controller 104, or both, can be considered as a part of an SoC along with the device 106 being internal or external to the SoC.

As shown in FIG. 1, the controller 104 can include a voltage regulation component 113. The voltage regulation component 113 can be resident on the controller 104. As used herein, the term “resident on” refers to something that is physically located on a particular component. For example, the voltage regulation component 113 being “resident on” the controller 104, for example, refers to a condition in which the hardware circuitry that comprises the voltage regulation component 113 is physically located on the controller 104. The term “resident on” may be used interchangeably with other terms such as “deployed on” or “located on,” herein. In some embodiments, the voltage regulation component 113 is part of the host 102, an application, or an operating system.

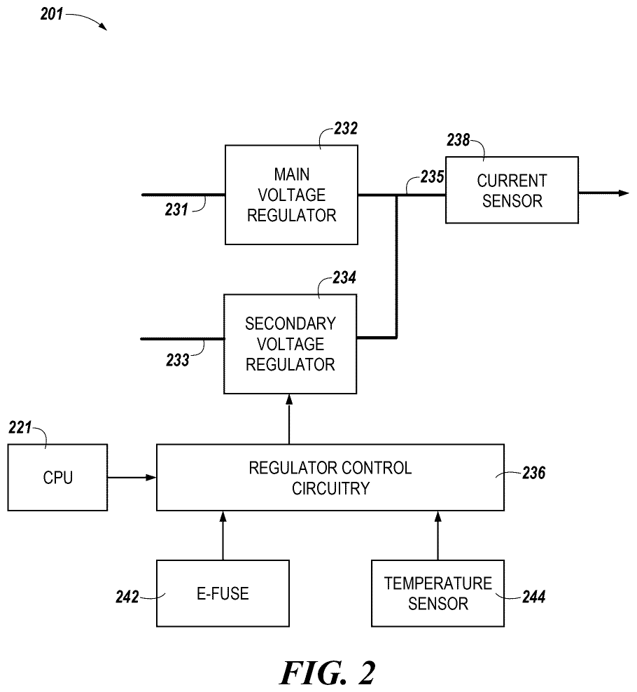

Although not shown in FIG. 1 so as to not obfuscate the drawings, the voltage regulation component 113 can include various circuitry to facilitate aspects of the disclosure described herein. For example, the voltage regulation component 113 can include various circuitry to facilitate controlling application of power supply signals generated at voltage regulators, such as voltage regulators 232, 234 illustrated in FIG. 2. Although not illustrated in FIG. 1, the voltage regulation component 113 can include a number of voltage regulators (e.g., including at least the main voltage regulator 232 and the secondary voltage regulator 234 illustrated in FIG. 2, herein) and/or regulator control circuitry (e.g., the control circuitry 236 illustrated in FIG. 2, herein).

FIG. 2 illustrates an example of a voltage regulation system 201 in accordance with some embodiments of the present disclosure. The example system 201, which can be referred to in the alternative as an “apparatus,” can be and/or be part of the electronic system 100 in FIG. 1. For example, a main voltage regulator 232, a secondary (“companion”) voltage regulator 234, regulator control circuitry 236, and/or a current sensor 238, or any combination thereof can be part of the voltage regulation components 113, which in turn can be part of the voltage regulation system 201. In some embodiments, the main voltage regulator 232 or the secondary voltage regulator 234, or both, can be a low dropout regulator (LDO), alternating current (AC)/direct current (DC) converter, DC/DC buck converter, switching capacitance, etc., although embodiments are not so limited. For example, the main voltage regulator 232 can be a DC/DC converter, while a secondary voltage regulator can be an LDO, although embodiments are not so limited.

The main voltage regulator 232 is coupled to a power line 231 (alternatively referred to as a “system power line” or “main power line”), via which a power supply signal is input to the main voltage regulator 232. The secondary voltage regulator 234 is coupled to another system power line 233, via which a power supply signal is input to the secondary voltage regulator 234. However, embodiments are not so limited. For example, both regulators 232 and 234 can be coupled to the same power line (as opposed to being respectively coupled to the power lines 231 and 233).

The main voltage regulator 232 and the secondary voltage regulator 234 are coupled to a power line 235 (e.g., alternatively referred to as a “regulated power line” and which can be a rail to provide a power supply signal from the respective voltage regulator to one or more electrical components to power such components). The main voltage regulator 232 can generate a power supply signal having a voltage regulated from a voltage of the signal received via the power line 231 and apply the generated the power supply signal to the power line 235. Similarly, the secondary voltage regulator 234 can generate a power supply signal having a voltage regulated from a voltage of the signal received via the power line 233 and apply the generated the power supply signal to the power line 235. In some embodiments, a voltage level of the power supply signal being input (e.g., provided, supplied, etc.) to the main voltage regulator can be different than that of the power supply signal being input to the secondary voltage regulator.

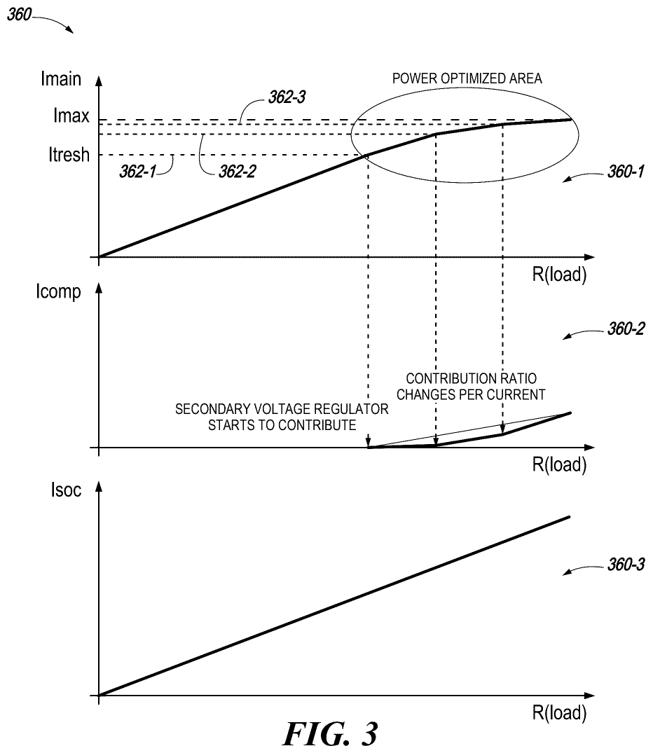

Although not illustrated in FIG. 2, the power line 231 can be split (diverted) into multiple “branch” power lines (e.g., with one of the branch power lines coupled to the main voltage regulator 232). The other branch power lines can be used to supply power supply signals to the other components, such as those components on a printed circuit board (PCB), those components on a Multi-Chip Module (MCM), and/or analog domain on the SoC, although embodiments are not so limited. Further, although not illustrated in FIG. 3, the power line 233 can be further split (diverted) into multiple “branch” power lines (e.g., with one of the branch power lines coupled to the secondary voltage regulator 234). The other branch power lines can be used to supply power supply signals to the other components, such as ONFI interfaces, regulators, etc. of (e.g., NAND) memory dice, although embodiments are not so limited.

The main voltage regulator 232 along with the secondary voltage regulator 234 can supply power (e.g., via the power line 235) to a circuit portion of the electronic system 100, such as a system-on-chip (SoC). The circuit portion can be a digital domain, or analog domain, or both (e.g., on the SoC) that can include various hardware that form one or more cores (e.g., “intellectual property (IP) cores”). As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein. However, embodiments are not so limited to a particular type of electrical device or circuit to which the main voltage regulator 232 and/or the secondary voltage regulator 234 can provide power supply signals for. For example, the main voltage regulator 232 and/or the secondary voltage regulator 234 can supply their output voltage and/or power supply signals to, but not limited to, microcontrollers, microprocessors, digital logic circuits, analog circuits, Light Emitting Diodes (LEDs), displays, sensors, motors, actuators, audio amplifiers, Radio Frequency (RF) circuits, test and measurement instruments (e.g., oscilloscopes, multimeters, etc.), automotive electronics, medical devices, telecommunication equipment, etc.

A current sensor 238 can be coupled to the power line 231 in a manner that measures a current level of a current flowing on the power line 235. The current sensor 238 can determine a current level of a current flowing on the power line 235 in relation to one or more thresholds (alternatively referred to as “threshold levels”). For example, the current sensor 238 can indicate whether the current level of the current flowing on the power line 235 has met or exceeded each threshold.

In one embodiment, the main voltage regulator 232 can operate alone (e.g., the secondary voltage regulator 234 is not in operation) until the indication is provided from the current sensor 238 to control circuitry 236 from the current sensor 238, which in turn can provide signaling to the secondary voltage regulator 234 to control operation of the secondary voltage regulator 234. As an illustrative, non-limiting example, the main voltage regulator 232 may operate by itself to regulate the voltage applied to the voltage power line 235 until the current sensor 238 indicates that the current flowing on the power line 231 has met or exceeded a very first threshold (e.g., the threshold 362-1 illustrated in FIG. 3 and corresponding to a lower current level than that of the other thresholds). Once such indication is provided to the regulator control circuitry 236, the regulator control circuitry 236 can provide signaling to the secondary voltage regulator 234 to cause the secondary voltage regulators 234 to be active (e.g., actively applying an output voltage to the power line 235) along with the main voltage regulators 232. The amount of current supplied by the secondary voltage regulator 234 can be a function of a ratio of the increase in monitored current. Further details of adjusting a ratio when a respective threshold has been met or exceeded are illustrated in and described in connection with FIG. 3.

In another embodiment, the secondary voltage regulator 234 can be a “low-current” regulator that can operate in a power-efficient manner particularly when the voltage regulation system 201 is not required to provide a high current to components (e.g., while the controller 104 and/or voltage regulation component 113 is in a power reduced mode, such as power off mode, sleep mode, etc.). For example, the secondary voltage regulator 234 can operate alone (e.g., the main voltage regulator 232 is not in operation) in the event that a corresponding component and/or a computing system can operate with a current low enough to make operating the main voltage regulator 232 (individually or in combination with the secondary voltage regulator 234) inefficient (e.g., power-inefficient).

As the current level of the current (e.g., as detected by the current sensor 238) on the power line 235 is required to increase, the control circuitry 236 can eventually control the main voltage regulator 232 to start contributing on the current flowing on the power line 235. For example, as an illustrative, non-limiting example, the secondary voltage regulator 234 may operate by itself to regulate the voltage applied to the voltage power line 235 until the current sensor indicates (e.g., determines) that the current level of the current flowing on the power line 231 has met or exceeded a lower threshold (corresponding to a lower current level than that of the other thresholds, such as thresholds 362-1, 362-2, 362-3 illustrated in FIG. 3 herein).

Once it is indicated by the current sensor 238 that the lower threshold has been met or exceeded, the regulator control circuitry 236 can provide signaling to the main voltage regulator 232 to cause the main voltage regulator 232 to be “active” (e.g., cause the main voltage regulator 232 to initiate application of its power supply signal to the power line 235). For example, when the lower threshold is determined to have been met or exceeded, the main voltage regulator 232 can be “active” initially along with the secondary voltage regulator 234. In one embodiment, as (e.g., the current level of) the current flowing on the system power line 231 increases (e.g., is determined to have met or exceeded another threshold corresponding to a current level higher than the lower threshold, but lower than the higher threshold mentioned above), the secondary voltage regulator 234 can gradually become “inactive” (e.g., not actively applying a power supply signal to the power line 235) such that the main voltage regulator 232 is active alone. As further illustrated in association with FIG. 3, the secondary voltage regulator 234 gradually becomes inactive by adjusting a ratio between current levels from the main and secondary voltage regulators 232, 234 for the respective amount of current on the power line 235 exceeding each threshold. This is to prevent issues such as power noise and voltage disruption caused by abrupt transitions between two voltage regulators 232 and 234. In another embodiment, the secondary voltage regulator 234 can become “inactive” substantially at the same time at which the main voltage regulator 232 became “active” (e.g., in response to the lower threshold is determined to have been met or exceeded). Further, as described above, once the higher threshold (e.g., the threshold 362-1 illustrated in FIG. 3 herein) described above is indicated as having been met or exceeded, the regulator control circuitry 236 can cause the secondary voltage regulator 234 to be active along with the main voltage regulator 232.

The regulator control circuitry 236 can be coupled to memory 242, a temperature sensor 244, and an CPU 221 (e.g., which can be analogous to the host 102 illustrated in FIG. 1). The memory 242 can be one or more fuses such as an electronic fuse (e-fuse), among other types of memory. The memory 242 can be configured to store a value that corresponds to process variations associated with a device (e.g., a device 106 illustrated in FIG. 1 and that can be a memory die). As used herein, a process variation can describe a variation of fabrication parameters. The process variations shown include slow-slow (SS), typical-typical (TT), and fast-fast (FF) process variations that correspond to process corners. However, the process variations shown are exemplary and other process variations can be utilized such as fast-slow and slow-fast, among others. In a number of embodiments, the process variation can be unique to the device (e.g., unique to each memory die) and/or may be a process variation assigned to the a set of memory dice in the unified manner.

The temperature sensor 244 can include hardware and/or firmware configured to measure a temperature and provide the temperature to the regulator control circuitry 236. The temperature sensor 244 can be part of the controller (e.g., the controller 104 of FIG. 1) or the device (e.g., device 106 of FIG. 1). The temperature sensor 244 can also be part of a host (e.g., the host 102 of FIG. 1), for example. The temperature sensor 244 can measure the temperature of an electronic system 100 or a portion of the electronic system 100. For example, the temperature sensor 244 can measure the temperature of a memory array and/or a bank of memory arrays, among others.

In a number of embodiments, the regulator control circuitry 236 can configure (e.g., adjust) a number of threshold levels (e.g., the threshold level 362-1, 362-2, 362-3, 364-1, 364-2, 364-3 illustrated in FIG. 3) at which the secondary voltage regulator 234 is controlled. For example, instead of operating the secondary voltage regulator 234 based on six threshold levels, such as threshold level 362-1, 362-2, 362-3, 364-1, 364-2, 364-3, the regulation control circuitry 236 can operate the secondary voltage regulator 234 based on ten different threshold levels, which allows a finer tuning of the secondary voltage regulator 234. Further, the control circuitry 236 can (e.g., dynamically) configure respective current levels and a ratio of the number of thresholds based on information accessed from the memory 242 and/or indications received from the temperature sensor 244.

FIG. 3 is a graph 360 that illustrates controlling respective current levels of different voltage regulation circuits (e.g., the main voltage regulator 232 and secondary voltage regulator 234 illustrated in FIG. 2) in accordance with some embodiments of the present disclosure. A graph 360-1 illustrates a current level supplied by the main voltage regulator 232 to the power line 235 illustrated in FIG. 2 as a function of conductivity (e.g., R⁻¹). Similarly, a graph 360-2 illustrates a current level supplied by the secondary voltage regulator 234 to the power line 235 as a function of the conductivity. Similarly, a graph 360-3 illustrates a current level (e.g., of the current flowing) on the power line 235 to the corresponding component (e.g., such as to a system on chip, abbreviated as “SoC”) as a function of the conductivity. More particularly, the current level illustrated at 360-3 corresponds to the current level on the power line 235 as contributed by the main voltage regulator 232 or the secondary voltage regulator 234 individually or by the main voltage regulator 232 and the secondary voltage regulator 234 collectively. Alternatively speaking, the current level illustrated at 360-3 corresponds to a sum of current levels supplied by the main voltage regulator 232 and the secondary voltage regulator 234 (e.g., as shown by 360-1 and 360-2).

As illustrated in FIG. 3, particularly at 360-2, the current level being increased on the power line 235 can be initially supplied by the secondary voltage regulator 234 alone and at least until the current flowing on the power line 235 reaches a threshold (e.g., a threshold current level) 364-1. Once the current on the power line 235 is determined to have reached the threshold 264-1, the main voltage regulator 232 can start contributing to the current flowing on the power line 235 along with the secondary voltage regulator 234. For example, when the threshold 364-1 is determined to have been met or exceeded, the main voltage regulator 232 can start supplying a current to the power line 235 with its current level (e.g., of the current being supplied by the main voltage regulator 232) constantly increasing (e.g., at a constant rate). Meanwhile, the current level supplied by the secondary voltage regulator 234 can remain constant between 364-1 and 364-2 as illustrated in FIG. 3. Once the current on the power line 235 is determined to have reached the threshold 364-2, the current level supplied by the main voltage regulator 232 can be increased at a higher rate. Meanwhile, the current level being supplied by the secondary voltage regulator 234 can be gradually decreased to the point where the secondary voltage regulator 234 eventually stop contributing to the current flowing on the power line 235. Once the current on the power line 235 is determined to have reached the threshold 364-3, the secondary voltage regulator 234 can stop contributing to the current flowing on the power line 235.

In the “Low Current Optimized Area” in FIG. 3 and in a different embodiment, the main voltage regulator 232 alone can supply a current to the power line 235. For example, the trend shown as a dotted line in the “Low Current Optimized Area” in 360-1 of FIG. 3 represents a current level supplied by the main voltage regulator 232 alone had the secondary voltage regulator 234 not contributed to the current flowing on the power line 235 (e.g., at least until the threshold 362-1 is determined to have been reached). In this scenario, there would be no current supplied by the secondary voltage regulator 234 in the “Low Current Optimized Area” (e.g., those trends illustrated in 360-2 in the “Low Current Optimized Area” would not exist).

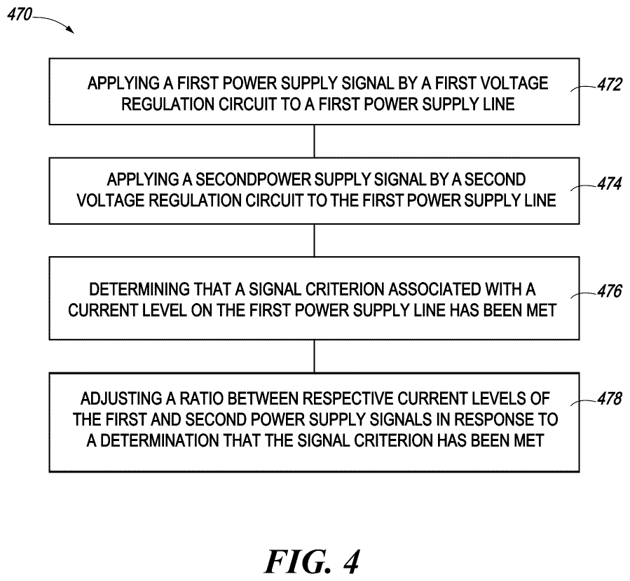

Subsequent to the current flowing on the power line 235 has reached or exceeded the threshold 364-3, the current being increased as illustrated in 360-3 can be entirely from the main voltage regulator 232 at least until the current level (e.g., of a current flowing) on the power line 235 reaches a threshold 362-1. Then, the current level (e.g., of the current) being supplied by the main voltage regulator 232 to the power line 235 saturates as it approaches a marginal current level (shown as “Imax” in 360-1 in FIG. 4) and is determined to have met or exceeded one or more thresholds. Although embodiments are not so limited, the marginal current level (“Imax”) can be 1.2 A. Meanwhile, the second voltage regulator 234 can contribute to the current level being increased as illustrated in 360-2 to compensate for the saturation shown in 360-1. The amount of current supplied by the secondary voltage regulator 234 can be a function of a ratio of the increase in monitored current on the power line 235. The ratio can vary depending on what threshold the current flowing on the power line 231 is determined to have met or exceeded.

For example, when the threshold 362-1 has been met or exceeded, the ratio can be 1:1 such that, for each additional 1 milliampere (mA) detected above the threshold 362-1, a compensation of 0.5 mA can be handled (e.g., contributed) by the secondary voltage regulator 234 and/or a compensation of 0.5 mA can be handled by the main voltage regulator 232. Continuing with this example, when the threshold 362-2 has been met or exceeded, the ratio can be adjusted to 3:1 such that, for each additional 1 mA detected above the threshold 362-2, a compensation handled by the secondary voltage regulator 234 can be increased to 0.75 mA, while a compensation handled by the main voltage regulator 232 is decreased to 0.25 mA. Further, when the threshold 362-3 has been met or exceeded, the ratio can be adjusted to 9:1 such that, for each additional 1 mA detected above the third threshold, a compensation handled by the secondary voltage regulator 234 can be increased to 0.9 mA, while a compensation handled by the main voltage regulator 232 is decreased to 0.1 mA. Embodiments are not limited to a particular number of thresholds for which the ratio can be adjusted by the regulator control circuitry 236. As a result, the contribution by secondary voltage regulator 234 as described above helps steady increase of the current on the power line 235 as shown in 360-3 despite of the saturation of the current level as shown in 360-1. This further helps eliminating and/or reducing the risk of the current being supplied from the main voltage regulator 232 crossing (being greater than) the “Imax” without disturbing the steady increase of the current flowing on the power 235.

FIG. 3 also illustrates the scenario where the main and secondary voltage regulator 232 and 234 operate based on a single threshold, such as the threshold 362-1. For example, the trends illustrated as dotted lines in the “High Current Optimized Area” of 360-1 and 360-2 respectively represent current levels supplied by the main and secondary voltage regulators 232 and 234 had the main and second voltage regulators 232 and 234 been operated solely based on the threshold 362-1. These trends illustrate that the current levels supplied from the main and secondary voltage regulators 232 and 234 are being increased with the constant slope once the threshold 362-1 is determined to have been reached, which indicate that the trends are not further adjusted based on the thresholds 362-2 and 362-3.

In contrast to the static approach where the activation point (e.g., determined based on a current level of the current flowing on the power line 235) of a companion voltage regulator (e.g., the secondary voltage regulator 234 illustrated in FIG. 2) remains fixed (such that the operation of the companion voltage regulator is not dynamically controlled once it starts operating), embodiments of the present disclosure can offer a more efficient means of reducing the power consumption by the companion voltage regulator by providing a dynamic control of both regulators (e.g., the main voltage regulator 232 and the secondary voltage regulator 234). As used herein, the term “dynamic control” of regulators refers to controlling respectively current levels of the regulators even subsequent to the regulators being activated (e.g., started applying signals on respective output power lines.

For example, the very first threshold level (“Itresh” 362-1 corresponding to the activation timing) can be of a higher current level than that of the scenario described above. The deliberate shift in activation point (e.g., current level) ensures that the secondary voltage regulator starts operating at a later current than the secondary voltage regulator in the scenario described above would have. While this can increase the risk of “Imax” being exceeded, the embodiments of the present disclosure can still mitigate this risk by causing the secondary voltage regulator to contribute “more” (by applying a power supply signal with the increased current level on the power line 235), which can dramatically saturate the current level (that has been increasing) through the main regulator as the current level approaches “Imax”. The results in a marginal optimization of the power consumption by avoiding unnecessarily early activation of the secondary voltage regulator and ensuring that it contributes significantly (thereby, incurring the increased inefficient power consumption) only when there's an imminent risk of the main regulator exceeding “Imax”.

FIG. 4 is a flow diagram corresponding to a method 470 for a voltage regulation system in accordance with some embodiments of the present disclosure. The method 470 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 470 is performed by the voltage regulation component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 472, the method 470 includes applying a first power supply signal by a first voltage regulation circuit (e.g., the main voltage regulator 232 illustrated in FIG. 2 herein) to a first power line (e.g., the regulated power line 235 illustrated in FIG. 2 herein) coupled to a circuit portion of an electronic system (e.g., the electronic system 100 illustrated in FIG. 1, herein). At operation 474, the method 470 includes applying a second power supply signal by a second voltage regulation circuit (e.g., the secondary voltage regulator 234 illustrated in FIG. 2 herein) to the first power line 235. At operation 476, the method 470 includes determining that a first signal criterion associated with a current flowing on the first power line 235 relative to a first threshold level (e.g., the threshold level 362-2) has been met. For example, the first signal criterion can be determined to have been met when (e.g., a current level of) the current flowing on the first power line 235 has reached or exceeded the first threshold level 362-2.

At operation 478, the method 470 includes adjusting (responsive to determining that the first signal criterion has been met) current levels respectively corresponding to the first and second power supply signals to cause the first voltage regulation circuit 232 and the second voltage regulation circuit 234 to contribute to a change in the current relative to the first threshold level 362-2 according to a first ratio.

In some embodiments, the method can further include determining that a second signal criterion associated with the current flowing on the first power line 235 relative to a second threshold level (e.g., the threshold level 362-3) has been met. For example, the second signal criterion can be determined to have been met when (e.g., a current level of) the current flowing on the first power line 235 has reached or exceeded the second threshold level 362-3. The second threshold level 362-3 can correspond to a higher current level than that of the first threshold level 362-2. In this example, the method can further include adjusting (responsive to the determination that the second signal criterion has been met) current levels respectively corresponding to the first and second power supply signals to cause the first and second power supply signals to contribute to a change in the current relative to the second threshold level 362-3 according to a second ratio. For example, a ratio can be increased from the first ratio to the second ratio responsive to determining that the second signal criterion has been met. The first ratio and the second ratio can respectively correspond to a current level corresponding to the second power supply signal to a current level corresponding to the first power supply signal.

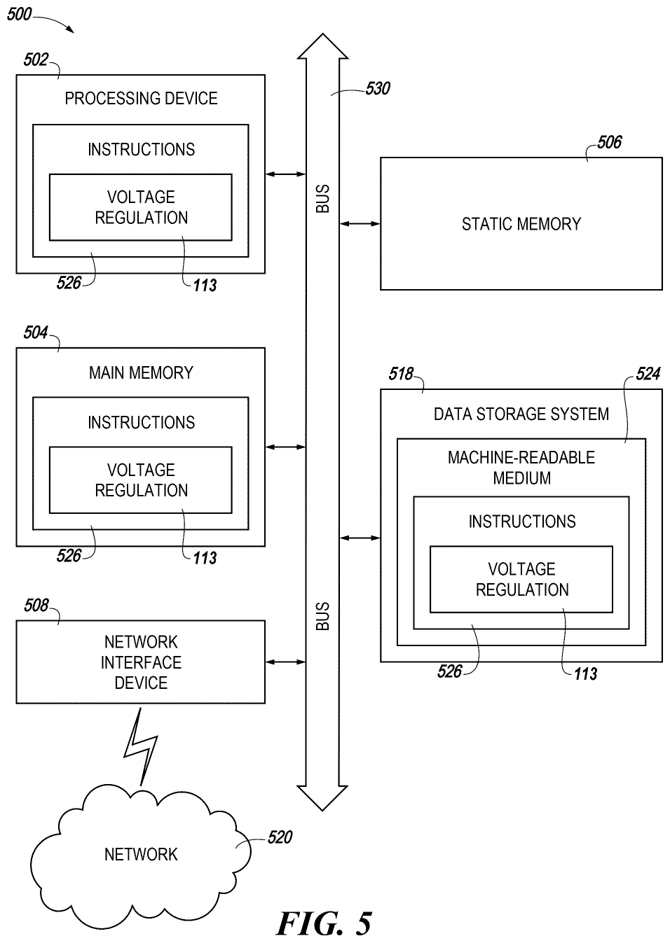

FIG. 5 is a block diagram of an example computer system in which embodiments of the present disclosure may operate. For example, FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the electronic system 100 of FIG. 1) or can be used to perform the operations of a controller (e.g., to execute an operating system to perform operations corresponding to the voltage regulation component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the electronic system 100 of FIG. 1 (e.g., the controller 104 of FIG. 1).

In one embodiment, the instructions 526 include instructions to implement functionality corresponding to voltage regulation component (e.g., the voltage regulation component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
applying a first power supply signal by a first voltage regulation circuit to a first power line;
applying a second power supply signal by a second voltage regulation circuit to the first power line;
determining that a first signal criterion associated with a current flowing on the first power line relative to a first threshold level has been met; and
adjusting, responsive to determining that the first signal criterion has been met, current levels respectively corresponding to the first and second power supply signals to cause the first and second voltage regulation circuits to contribute to a change in the current relative to the first threshold level according to a first ratio.

2. The method of claim 1, wherein determining that the first signal criterion has been met further comprises determining that the current flowing on the first power line has reached or exceeded the first threshold level.

3. The method of claim 1, further comprising:
determining that a second signal criterion associated with the current flowing on the first power line relative to a second threshold level has been met; and
adjusting, responsive to the determination that the second signal criterion has been met, current levels respectively corresponding to the first and second power supply signals to cause the first and second power supply signals to contribute to a change in the current relative to the second threshold level according to a second ratio.

4. The method of claim 3, wherein:
the second threshold level corresponds to a higher current level than that of the first threshold level; and
the method further comprises increasing a ratio from the first ratio to the second ratio responsive to determining that the second signal criterion has been met, wherein the first ratio and the second ratio respectively correspond to a current level corresponding to the second power supply signal to a current level corresponding to the first power supply signal.

5. The method of claim 3, wherein determining that the second signal criterion has been met further comprises determining that the current flowing on the first power line has reached or exceeded the second threshold level.

6. An apparatus, comprising:
a first voltage regulation circuit configured to apply a first power supply signal to a first power line and to contribute to a current flowing on the first power line;
a second voltage regulation circuit configured to apply a second power supply signal to the first power line and to contribute to the current flowing on the first power line; and
control circuitry coupled to the first voltage regulation circuit and the second voltage regulation circuit, wherein the control circuitry is configured to, while the first and second power supply signals are being applied to the first power line:
determine that the current flowing on the first power line has reached or exceeded a first threshold level; and
adjust current levels respectively corresponding to the first and second power supply signals to cause the first and second voltage regulation circuits to contribute to an amount of current exceeding the first threshold level according to a first ratio.

7. The apparatus of claim 6, wherein the control circuitry is configured to prevent the second voltage regulation circuit from contributing to the current flowing on the first power line unless the current flowing on the first power line is determined to have reached or exceeded a second threshold level, wherein the second threshold level corresponds to a lower current level than that of the first threshold level.

8. The apparatus of claim 7, wherein the control circuitry is further configured to allow the second voltage regulation circuit to apply the second power supply signal to the first power line to contribute to the current flowing on the first power line in response to the current flowing on the first power line is determined to have reached or exceeded the second threshold level.

9. The apparatus of claim 8, wherein the control circuitry is further configured to:
determine that the current flowing on the first power line has reached or exceeded a third threshold level corresponding to a higher current level than that of the first threshold level; and
adjust current levels respectively corresponding to the first and second power supply signals to cause the first and second voltage regulation circuits to contribute to an amount of current exceeding the second threshold level according to a second ratio.

10. The apparatus of claim 9, wherein the second ratio corresponds to a higher ratio of a current level corresponding to the second power supply signal to a current level corresponding to the first power supply signal than the first ratio.

11. The apparatus of claim 6, further comprising:
sensing circuitry coupled to the first power line; and
the sensing circuitry is configured to compare the current flowing on the first power line to a plurality of threshold levels.

12. The apparatus of claim 11, further comprising a memory configured to store information associated with a process variation associated with at least a part of the apparatus and coupled to the control circuitry, wherein the control circuitry is configured to:
access the memory to retrieve the information; and
adjust the plurality of threshold levels based on the information.

13. The apparatus of claim 6, wherein the second voltage regulation circuit is configured to regulate a voltage of an input power supply signal received via a second power line, wherein the voltage of the input power supply signal corresponds to a first voltage level.

14. The apparatus of claim 11, wherein the first voltage regulation circuit is configured to regulate a voltage of an input power supply signal received via a third power line, wherein the voltage of the input power supply signal corresponds to a second voltage level different than the first voltage level.

15. A system, comprising:
a first voltage regulation circuit configured to apply a first power supply signal to a first power line;
a second voltage regulation circuit configured to apply a second power supply signal to the first power line;
a sensor configured to monitor a current flowing on the first power line based on a plurality of programmable threshold levels; and
control circuitry coupled to the sensor, the first voltage regulation circuit, and the second voltage regulation circuit, the control circuitry configured to:
cause, in response to an indication from the sensor that a current flowing on the first power line has reached or exceeded a first threshold level, the second voltage regulation circuit to initiate the application of the second power supply signal to the first power line to cause the first and second voltage regulation circuits to contribute to an amount of current exceeding the first threshold level according to a first ratio; and
adjust, in response to an indication from the sensor that the current flowing on the first power line has reached or exceeded a second threshold level corresponding to a higher current level than that of the first threshold level, respective current levels corresponding to the first and second power supply signals to cause the first and second voltage regulation circuits to contribute to an amount of current exceeding the second threshold level according to a second ratio.

16. The system of claim 15, wherein the control circuitry is further configured to, in response to an indication provided by the sensor that the current flowing on the first power line has not reached or not exceeded a third threshold level:
cause the second regulation circuit to apply a third power supply signal to the first power line to contribute to a current flowing on the first power line; and
prevent the first regulation circuit from contributing to the current flowing on the first power line.

17. The system of claim 16, wherein the control circuitry is further configured to cause the first regulation circuit to apply a fourth power supply signal to the first power line to cause the first and second voltage regulation circuits to contribute to an amount of current exceeding the third threshold level according to a third ratio in response to an indication provided by the sensor that the current flowing on the first power line signal has reached or exceeded the third threshold level.

18. The system of claim 17, wherein the control circuitry is further configured to, in response to an indication provided by the sensor that a current level on the first power line signal has reached or exceeded a fourth threshold level corresponding to a higher current level than that of the third threshold level:
adjust current levels respectively corresponding to the third and fourth power supply signals to cause the first and second voltage regulation circuits to contribute to an amount of current exceeding the fourth threshold level according to a fourth ratio.

19. The system of claim 18, wherein the fourth ratio corresponds to a higher ratio of a current level corresponding to the fourth power supply signal to a current level corresponding to the third power supply signal than the third ratio.

20. The system of claim 15, further comprising a temperature sensor coupled to the control circuitry, wherein the control circuitry is configured to adjust at least one threshold level of the plurality of programmable threshold levels based on an indication provided by the temperature sensor.
